(19) United States
(12) Patent Application Publication
(10) Pub. No.: US 2026/0143604 A1
(43) Pub. Date: May 21, 2026

(54) Multi-Function Hinge

(71) Applicant: Microsoft Technology Licensing, LLC, Redmond, WA (US)

(72) Inventors: Jinger Sia CHONG, Cambridge, MA (US); Denys YAREMENKO, Carnation, WA (US); Brett TOMKY, Seattle, WA (US); Devin CAPLOW-MUNRO, Seattle, WA (US)

(73) Assignee: Microsoft Technology Licensing, LLC, Redmond, WA (US)

(21) Appl. No.: 18/953,995

(22) Filed: Nov. 20, 2024

(51) Int. Cl. H05K 5/02; F16C 11/04

(52) U.S. Cl. CPC H05K 5/0226; F16C 11/04

(57) ABSTRACT

The description relates to hinged devices, such as hinged computing devices and accessories. One example can include a first portion and a second portion that are rotatably secured by a hinge shaft through a range of rotation from a closed orientation to a fully open orientation. A friction sub-assembly can be positioned on the hinge shaft and configured to create resistance to rotation during a first sub-range of rotation that ranges from the fully opened orientation to an intermediary orientation. A biasing sub-assembly can be positioned on the hinge shaft and configured to create a bias force during a second sub-range of rotation that ranges from the intermediary orientation to the closed orientation and the biasing force biases the first and second portions to an individual orientation within the second sub-range of rotation.

### BACKGROUND

Consumers rely on many portable computer form factors in their busy lives. Some of these portable computers can include a hinge or work cooperatively with a hinge to allow the device to be orientated to different postures. For instance, smart phones, tablets, and notebook computers can provide enhanced functionality by folding for storage and opening for use. Many hinge designs have been tried for folding the device portions.

### SUMMARY

This patent relates to hinged devices, such as hinged computing devices and hinges associated with these devices, such as hinges on accessory devices. The hinges can provide different functionalities at different device orientations. One example can include a first portion and a second portion that are rotatably secured by a hinge shaft through a range of rotation from a closed orientation to a fully open orientation. A friction sub-assembly can be positioned on the hinge shaft and configured to create resistance to rotation during a first sub-range of rotation that ranges from the fully opened orientation to an intermediary orientation. A biasing sub-assembly can be positioned on the hinge shaft and configured to create a bias force during a second sub-range of rotation that ranges from the intermediary orientation to the closed orientation and the biasing force biases the first and second portions to an individual orientation within the second sub-range of rotation.

This example is intended to provide a summary of some of the described concepts and is not intended to be inclusive or limiting.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the figure and associated discussion where the reference number is first introduced. Where space permits, elements and their associated reference numbers are both shown on the drawing page for the reader's convenience. Otherwise, only the reference numbers are shown. Note that some figures illustrate many elements and adding lead lines to all of the elements can diminish readability of the figure. Accordingly, not every element is designated in every figure.

FIGS. 1A-1D, 2A-2C, 3C-3H, 4A, and 4B show perspective views of example devices in accordance with some implementations of the present concepts.

FIGS. 3A and 3B show exploded perspective views of example devices in accordance with some implementations of the present concepts.

### DESCRIPTION

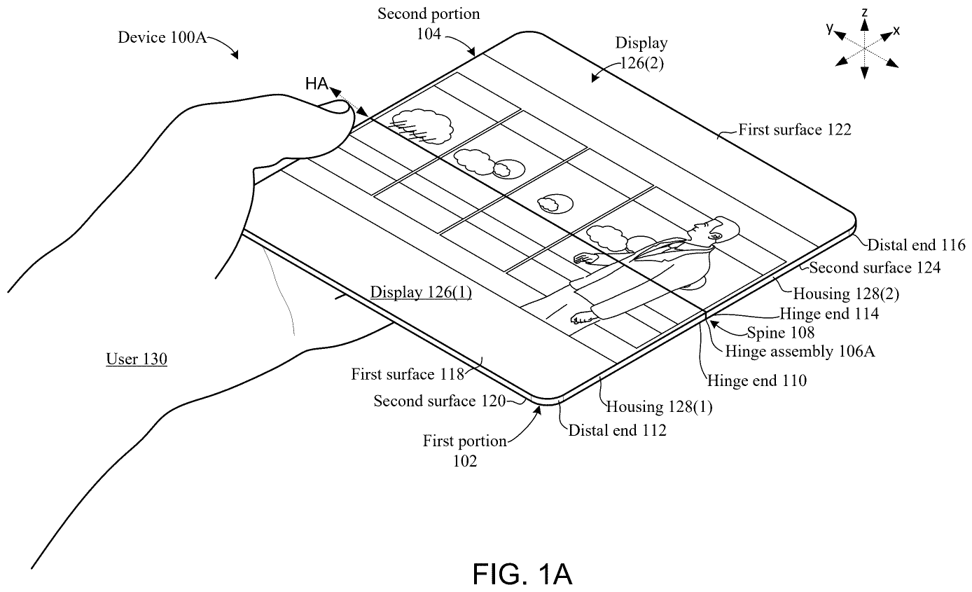

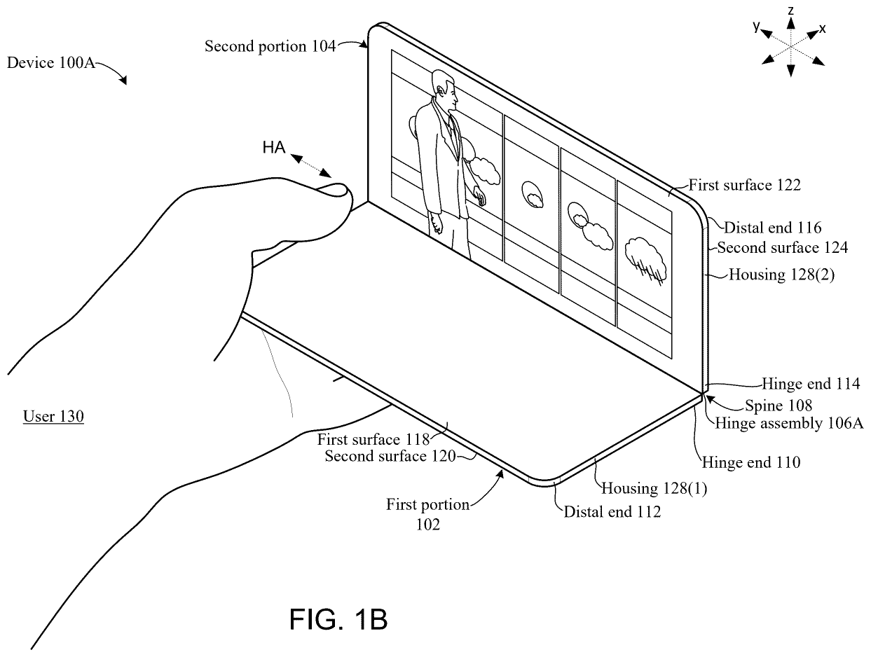

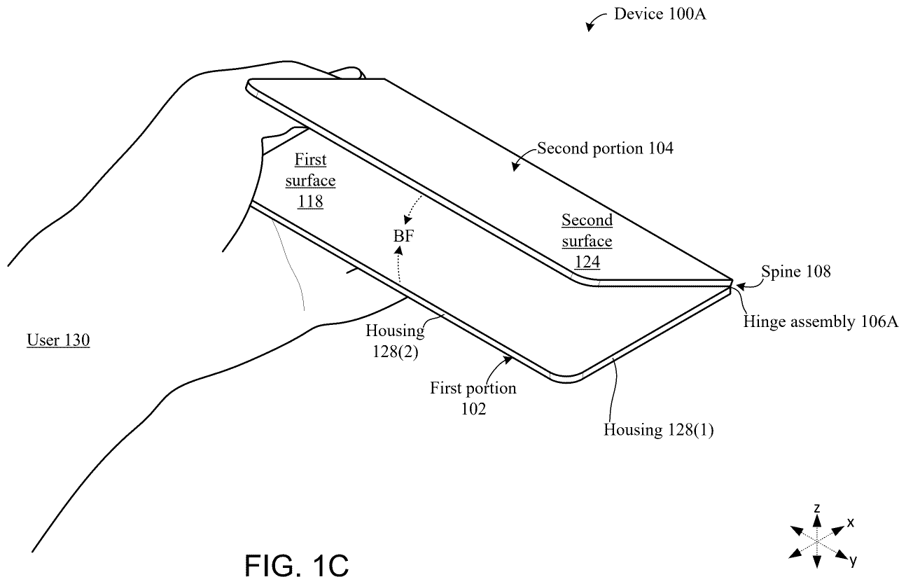

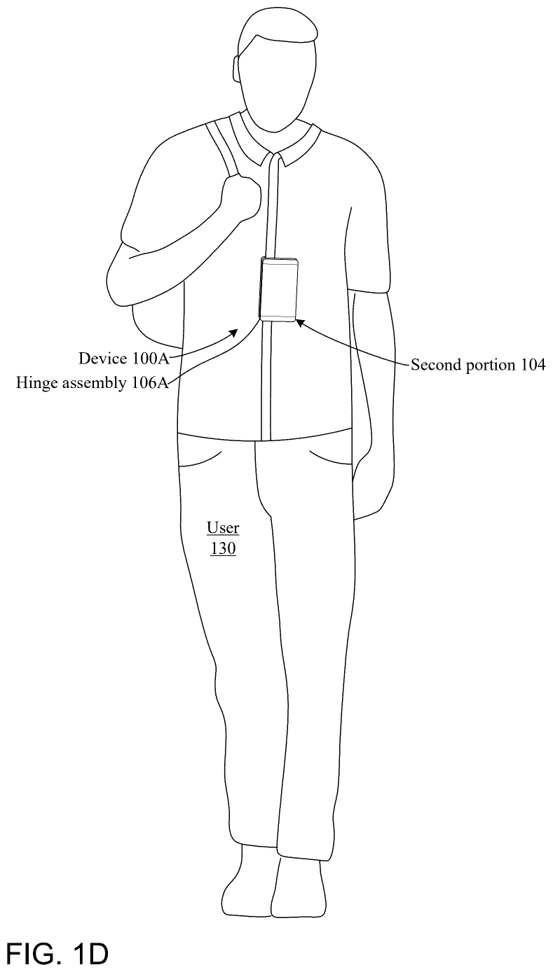

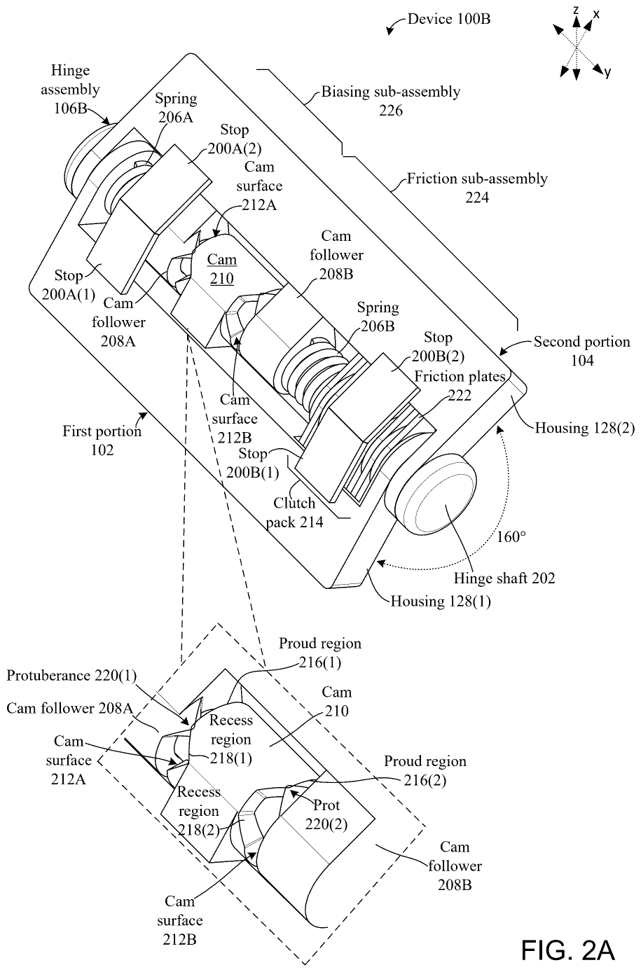

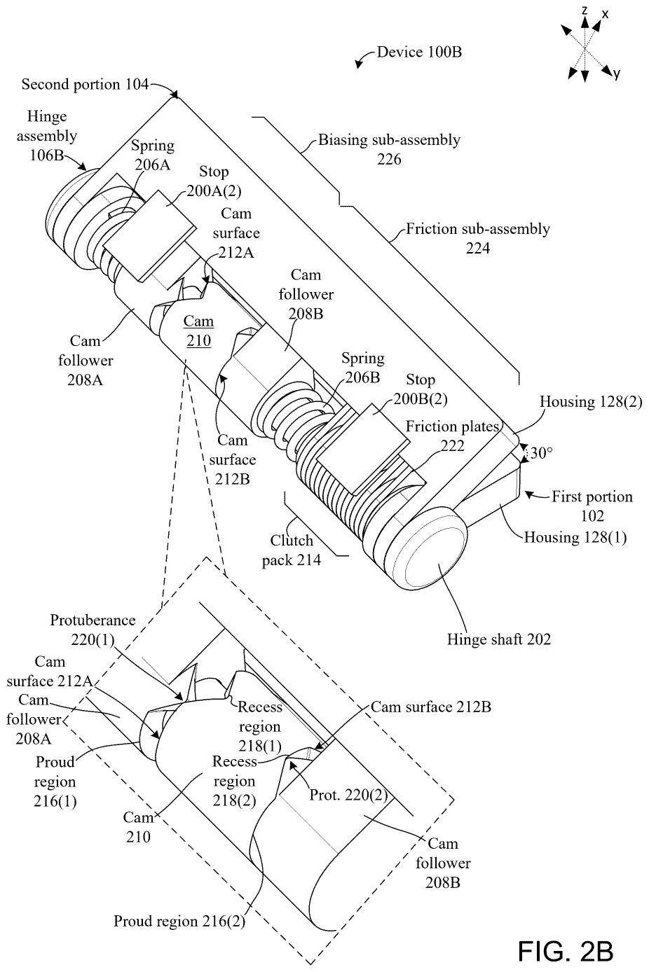

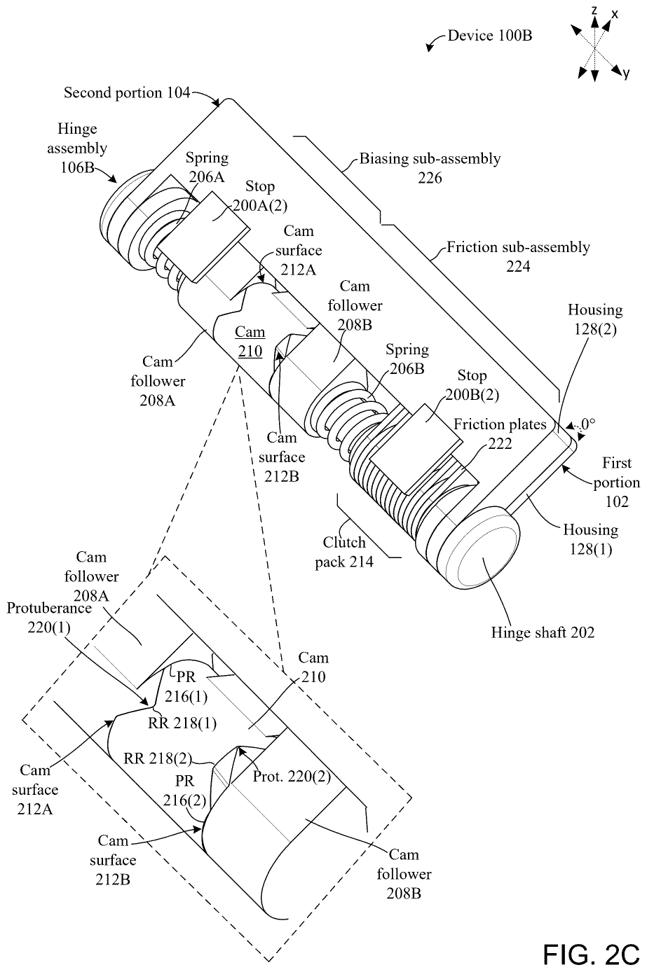

The present concepts relate to devices, such as computing devices employing dual function hinge assemblies that can rotationally secure/couple first and second device portions. The dual function hinge assembly can define a range of rotation for the first and second portions from fully opened to closed. The present concepts can provide different hinge functionalities depending on the orientation of the device portions. In one sub-range of orientations, such as fully opened to 30 degrees, the present concepts can provide a friction hinge functionality and at another sub-range of orientations, such as 30 degrees to closed, the present concepts can provide a biasing hinge functionality. These aspects are described in more detail below beginning with FIGS. 1A-1D. Further, the present concepts can accomplish both of these functionalities with sub-assemblies positioned on a single hinge shaft. In some cases, the friction hinge functionality can be provided by a friction sub-assembly and the biasing functionality can be provided by a biasing sub-assembly. These aspects are described in more detail below beginning with FIGS. 2A-2C.

Introductory FIGS. 1A-1D collectively show an example device 100A that has first and second portions 102 and 104 that are rotatably secured together by a dual function hinge assembly (hereinafter, “hinge assembly”) 106A positioned in a spine 108. The hinge assembly 106A defines a hinge axis HA around which the first and second portions rotate. (The use of the alphabetic suffixes ‘A,’ ‘B,’ etc. relative to the device 100A and the hinge assembly 106A indicate that multiple different device form factors and multiple different hinge assembly form factors are described.)

The first portion 102 can extend from a hinge end 110 to a distal end 112. The second portion 104 also can extend from a hinge end 114 to a distal end 116. The first portion 102 can include opposing first and second major surfaces 118 and 120 (hereinafter, first and second surfaces). Similarly, the second portion 104 can include opposing first and second major surfaces 122 and 124 (hereinafter, first and second surfaces).

In some implementations, displays 126 are supported by housings 128. For example, the displays 126 can be positioned on the first and/or second surfaces 118, 120, 122, and/or 124, respectively. In the illustrated configuration, the displays 126 are positioned on first surfaces 118 and 122, respectively.

The hinge assembly 106A can rotatably secure the first and second portions through a range of orientations including a closed orientation and various open orientations. The hinge assembly entails a technical solution that provides two distinct functionalities during the range of orientations. In a first sub-range of rotations, the hinge assembly provides a ‘retention’ or ‘friction’ force that acts to maintain the device portions at the orientation the user selects. In a second sub-range of rotations, the hinge assembly provides a bias force that acts to rotate the device portions to a specific orientation. In this implementation, the first sub-range of rotation is from about 180 degrees to about 30 degrees and the second sub-range of rotation is from about 30 degrees to about zero degrees. Further, in this implementation, the specific orientation is the closed orientation. Thus, from about 180 degrees to about 30 degrees, the hinge assembly provides a technical solution that holds the device at whatever specific orientation the user selects. Below 30 degrees, the hinge assembly creates a bias to close the device toward zero degrees. Stated another way, when the device is in orientations from 30 degrees to zero degrees, the device creates a bias towards the zero degree orientation. Once at the zero-degree (e.g., closed) orientation (e.g., closed), the device continues to create the bias to maintain the closed orientation. This technical solution aids in closing the device for carrying and for creating a clamping affect that increases carrying options and decreases chances of losing the device.

FIGS. 1A and 1B show the device 100A at representative orientations of the first sub-range of rotation. FIGS. 1C and 1D show the device at representative orientations of the second sub-range of rotation. In the first sub-range of rotation, the hinge assembly 106A supplies the retention force that contributes to maintaining the device at the present orientation (e.g., posture). For instance, FIG. 1A shows user 130 holding the device 100A at a 180-degree orientation (e.g., the first and second portions 102 and 104 define a 180-degree angle). The retention force maintains the device unless another force is exerted on the device, such as by the user. Thus, the hinge assembly's retention force maintains the device at the 180-degree orientation while the user holds and uses it. In this implementation, the 180-degree orientation represents the fully open orientation. However, other implementations can have a fully open orientation that is less than 180 degrees or more than 180 degrees.

For purposes of explanation, assume at this point the user wants to reduce the orientation of the device and exerts a closing force on the first and second portions. FIG. 1B shows the device rotated to the 90-degree orientation, which is still in the first sub-range of rotation. At this point, the user stops closing the device and the retention force maintains the device at the 90-degree orientation. Thus, the device maintains a ‘notebook’ configuration where the user can utilize the first portion 102 as an input device while viewing content on the second portion 104. The illustrated 90-degree orientation is within the first sub-range of rotation and the retention force holds the device at the orientation. This continues as the user rotates the device portions toward one another in the closing direction through the remaining orientations of the first sub-range of rotation. Recall that in this implementation, the first sub-range of rotation ends at about a 30-degree orientation. As the device passes the 30-degree orientation, the device transitions from the first sub-range of rotation to the second sub-range of rotation. Accordingly, the device transitions from the retention force of the first sub-range of rotation to the bias force of the second sub-range of rotation. This is illustrated in FIG. 1C.

FIG. 1C shows the device continuing to rotate in the closing direction to about a 25-degree orientation due to force imparted by the user. Now, in the second sub-range of rotation (starting at 30 degrees), the biasing force creates a bias on the device portions toward a specific orientation. The bias force is represented by bias force (BF) arrow on FIG. 1C. The bias force will cause the device to rotate in the second sub-range of orientations toward the specific orientation without other external forces, such as those applied by the user. In this example, the specific orientation is the closed or zero-degree orientation, which is shown in FIG. 1D. The bias force causes the device to automatically rotate the first and second device portions toward one another in the closing direction until reaching the specific orientation or until countered by another stronger force.

FIG. 1D shows the bias force biasing the first and second portions 102 and 104 towards the closed orientation. In this case, the bias force is sufficient to clamp the device onto an object, such as the user's shirt. Here, the bias force is large enough to keep the device from falling off as the user undertakes various activities. Thus, the bias force in the closing direction helps the user close the device and provides an attachment means so the device can be temporally attached to various objects. The present concepts provide a technical solution for a dual function hinge assembly. The hinge assembly provides the first function in the first sub-range of rotation and the second function in the second sub-range of rotation. These aspects are described in more detail below.

Note also that if the specific orientation is an orientation in the second sub-range of rotation other than the closed orientation, then the bias could be in both the closing and opening directions. For instance, if the second sub-range of rotation is closed to 30 degrees and the specific orientation is fifteen degrees, the device could provide an opening bias from closed to 15 degrees and a closing bias from 30 degrees to 15 degrees.

FIGS. 2A-2C collectively show an example hinge assembly 106B that provides the dual functionality introduced above relative to FIGS. 1A-1D. The sequence of FIGS. 2A-2C is similar to those of FIGS. 1A-1D in that the sequence starts at the fully open orientation of FIG. 2A and rotates through a range of intermediate open orientations (represented by FIG. 2B) and finishes with the closed orientation of FIG. 2C. The hinge assembly 106B works cooperatively with stops 200A and 200B. The stops 200A(1) and 200B(1) are associated with first portion 102 and stops 200A(2) and 200B(2) are associated with second portion 104. The stops 200A and 200B contact one another to define the fully open orientation shown in FIG. 2A. In this implementation, the fully open orientation is about 160 degrees.

In this implementation, the hinge assembly 106B includes hinge shaft 202. Positioned along the hinge shaft 202 are a first compression spring (hereinafter, may be ‘spring’) 206A, a first cam follower 208A, an axial cam (hereinafter, may be ‘cam’) 210 that includes two cam surfaces 212, a second cam follower 208B, a second compression spring 206B, and a clutch pack 214. Each of the cam surfaces 212 includes proud regions 216 (may be abbreviated as ‘PR’ on drawing page for space savings) and recess regions 218 (may be abbreviated as ‘RR’ on drawing page for space savings). The cam followers 208 include protuberances 220 that engage the cam surfaces 212 of the axial cam 210. (Protuberances 220 may be shortened to ‘prot’ on the drawing page for space savings.) Thus, a single cam 210 with opposing cam surfaces 212A and 212B can independently control both of the cam followers 208A and 208B.

The clutch pack 214 includes a set of friction plates 222, only one of which is designated to avoid clutter on the drawing page. The compression springs 206, axial cam 210, cam followers 208, friction plates 222, and portions of the housings 128(1) and 128(2) are positioned on (e.g., coextensive with) the hinge shaft 202. Stated another way, the hinge shaft 202 passes through holes defined in these elements. For instance, each friction plate 222 defines a hole through which the hinge shaft 202 passes. Alternating friction plates 222 extend to the first and second portions 102 and 104.

The cam 210 is secured to the first portion 102 in a manner which prevents the cam 210 from moving along the hinge shaft 202 (e.g., in the y reference direction). In contrast, the cam followers 208 are secured to the second portion 104 in a manner that allows the cam followers to move along the hinge shaft 202 (e.g., in the y reference direction). Movement of the cam followers 208 along the hinge shaft 202 (e.g., in the y reference direction) occurs when the first and second portions are rotated relative to one another (e.g., the orientation changes). Movement of cam follower 208A in the y reference direction can affect the extent of compression of compression spring 206A. Similarly, movement of cam follower 208B in the y reference direction can affect the extent of compression of compression spring 206B.

From one perspective, the cam 210 (with cam surface 212B), cam follower 208B, compression spring 206B, and clutch pack 214 can function as a friction sub-assembly 224. The friction sub-assembly 224 operates in a first sub-range of orientations to create a friction force (e.g., resistance to rotation) that operates to hold the device at its present orientation within the first sub-range of orientations. Similarly, the cam 210 (with cam surface 212A), cam follower 208A, and compression spring 206A can function as a biasing sub-assembly 226. The biasing sub-assembly 226 operates in a second sub-range of orientations to bias the first and second portions to a specific orientation with the second sub-range of orientations. Both the friction sub-assembly 224 and the biasing sub-assembly 226 are positioned on the hinge shaft 202. Thus, the friction sub-assembly 224 and the biasing sub-assembly 226 contribute to the technical solution of the dual function hinge. Further, locating both sub-assemblies on a single hinge shaft provides a technical solution that saves space (e.g., device real estate) in the hinge assembly and decreases the number of components employed to achieve the dual functionality.

The 160-degree orientation of FIG. 2A represents an endpoint of the first sub-range of orientations. At this point, the friction sub-assembly 224 is creating a retention or friction force (e.g., resistance to rotation) that functions to hold the device at the present orientation. Specifically, protuberance 220(2) of cam follower 208B is contacting the proud region 216(2) of cam surface 212B. The contact with the proud region 216(2) is creating a linear force on, and moving, the cam follower 208B in the +y reference direction against the compression spring 206B. The compression spring 206B is captive between the cam follower 208B and the clutch pack 214. As such, the movement of the cam follower 208B compresses the compression spring 206B against the clutch pack 214 in the +y reference direction.

The clutch pack 214 is captive between the compression spring 206B and the end of the first portion 102. As such, the compression spring 206B imparts a linear force in the +y reference direction on the clutch pack 214. The linear force compresses adjacent friction plates 222 against one another. Recall that alternating friction plates 222 extend to the first and second portions 102 and 104. The linear compressive force increases the resistance to rotation experienced by adjacent friction plates 222 and thus the first and second portions. Thus, the friction sub-assembly 224 is providing a technical solution by creating a friction force that functions to hold the device at the present orientation. Alternatively or additionally to a clutch pack, the friction sub-assembly could employ a set of detents that are configured to maintain the first and second portions at individual orientations in the first sub-range of orientations.

At this 160-degree orientation, which lies in the first sub-range of rotation, the biasing sub-assembly 226 is not creating a biasing force. More specifically, the protuberance 220(1) of cam follower 208A is contacting the proud region 216(1) of cam surface 212A. This contact is moving the cam follower 208A in the −y reference direction and compressing the compression spring 206A. The proud region 216(1) is generally flat when viewed axially along the hinge axis. Thus, the cam follower 208A is not biased toward or away from the present orientation. Accordingly, the biasing sub-assembly 226 is not creating a biasing force on the first and second portions toward or away from the present orientation. This configuration provides a technical solution in that the biasing sub-assembly 226 is not creating a biasing force in the first sub-range of rotation that counters (e.g. acts against) the retention force generated by the friction sub-assembly 224.

FIG. 2B shows an approximately 30-degree orientation that represents a transition from the first sub-range of rotation (e.g., 160 degrees to 30 degrees) to the second sub-range of rotation (e.g., 30 degrees to zero degrees). At this point, in relation to biasing sub-assembly 226, the compression spring 206A remains compressed by the cam follower 208A. However, the protuberance 220(1) is transitioning from the proud region 216(1) of cam surface 212A to the recess region 218(1). In the recess region 218(1) the cam surface 212A is sloped. The compressed compression spring 206A continues to impart linear forces on the cam follower 208A in the +y reference direction. These linear forces create a bias for the protuberance 220(1) to move down the sloped surface of the recess region 218(1), which would allow the cam follower 208A to move away from the compression spring 206A and allow the compression spring 206A to decompress.

Recall that the cam 210 is secured to the first portion 102 while the cam follower 208A is secured to the second portion. Thus, the biasing sub-assembly 226 is beginning to create a bias on the first and second portions toward an orientation that results from the compression spring pushing the cam follower's protuberance 220(1) into recess region 218(1). In this case, the protuberance 220(1) is fully in the recess region 218(1) at the closed orientation of FIG. 2C. Given that the cam follower 208A is secured to the second portion 104 and the cam 210 is secured to the first portion 102, the interaction of the protuberance 220(1) with the recess region 218(1) is beginning to create a bias on the first and second portions to rotate to the closed orientation.

At this point, in relation to friction sub-assembly 224 recall that during the first sub-range of orientations, the cam 210 had moved the cam follower 208B against and compressing the compression spring 206B. The compression spring 206B in turn imparted a force on the friction plates 222 that increased friction (e.g., resistance to rotation) between adjacent friction plates 222. Now, at the 30-degree orientation, the protuberance 220(2) of cam follower 208B of the cam surface 212B is in the recess region 218(2). The compression spring 206B has moved the cam follower 208B in the −y reference direction and thus the compression spring 206B can decompress.

As the compression spring 206B decompresses, the linear force imparted by the compression spring 206B on the clutch pack 214 is reduced and then eliminated as the spring continues to decompress. This removal of the lateral force reduces the resistance to rotation provided by the adjacent friction plates 222 of the clutch pack 214. Thus, the clutch pack 214 no longer provides a retention force to maintain the device (e.g., the first and second portions) at its present orientation. This provides a technical solution in that the friction sub-assembly 224 is not creating resistance to rotation that would counter (e.g., act against) the bias force created by the biasing sub-assembly 226 in the second sub-range of rotation. Thus, the biasing sub-assembly 226 is unencumbered as it biases the first and second portions toward a specific orientation. In this implementation, the specific orientation is the orientation where the protuberance 220(1) is in the bottom of the recess region 218(1). In this case, the protuberance 220(1) is in the bottom of the recess region 218(1) in the zero degree or closed orientation as shown in FIG. 2C. Stated another way, the present concepts provide a technical solution in that the biasing sub-assembly 226 and the friction sub-assembly 224 do not counteract or ‘fight’ one another. Instead, one functions in one sub-range of rotation and the other functions in a different sub-range of rotation in a complementary manner. Without this technical solution, larger friction forces would be required in the friction sub-range and larger biasing forces would be required in the biasing sub-range. Instead, the present concepts provide a technical solution that allows reduced forces to accomplish the desired functionality and reduces stress on the device components that would occur with competing forces at a given orientation.

FIG. 2C shows the first and second portions 102 and 104 biased to the closed orientation by the biasing sub-assembly 226. In this implementation, at this orientation, in relation to the biasing sub-assembly 226, the protuberance 220(1) is in the bottom of the recess region 218(1) and is creating a bias to maintain this orientation. At this orientation (and other orientations in the second sub-range of rotation) in relation to the friction sub-assembly 224, the protuberance 220(2) of cam follower 208B is fully in recess 218(2), which allows the cam follower 208B to move in the −y reference direction. The movement of the cam follower 208B removes pressure on the compression spring 206B and allows the compression spring 206B to extend (decompress). The compression spring 206B in turn is no longer imparting lateral forces on the clutch pack 214. Correspondingly, the friction plates 222 are no longer forced against one another and thus do not provide resistance to rotation.

Thus, at this closed orientation of FIG. 2C, the biasing sub-assembly 226 is controlling hinge function and is biasing the first and second portions to maintain this orientation. The hinge assembly 106B will cause the first and second portions 102 and 104 to maintain this orientation unless the user imparts a rotational force (e.g., torque) on the first and second portions sufficient to overcome the bias by causing the protuberance 220(1) to move out of recess region 218(1), up the cam surface 212A to the proud region 216(1) while compressing compression spring 206A.

In the second sub-range of rotation that occurs from approximately 30 degrees to zero degrees in the illustrated implementation, the effects of the friction sub-assembly 224 diminish and the effects of the biasing sub-assembly 226 increase. The effects of the friction sub-assembly 224 are nominal once the movement of the cam follower 208B in the −y reference direction allows compression spring 206B to fully decompress. In contrast, the effects of the biasing sub-assembly 226 are significant as the protuberance 220(1) of cam follower 208A travels down the sloped cam surface 212A of the recess region 218(1). The force of compression spring 206A on the protuberance 220(1) creates the bias by causing the protuberance 220(1) to continue down the sloped cam surface 212A until the protuberance 220(1) is bottomed out in the recess region 218(1). Overcoming this bias entails a user imparting enough rotational force (e.g., torque) to cause the protuberance 220(1) to move up the sloped cam surface 212A of the recess region 218(1) and thereby compress the compression spring 206A.

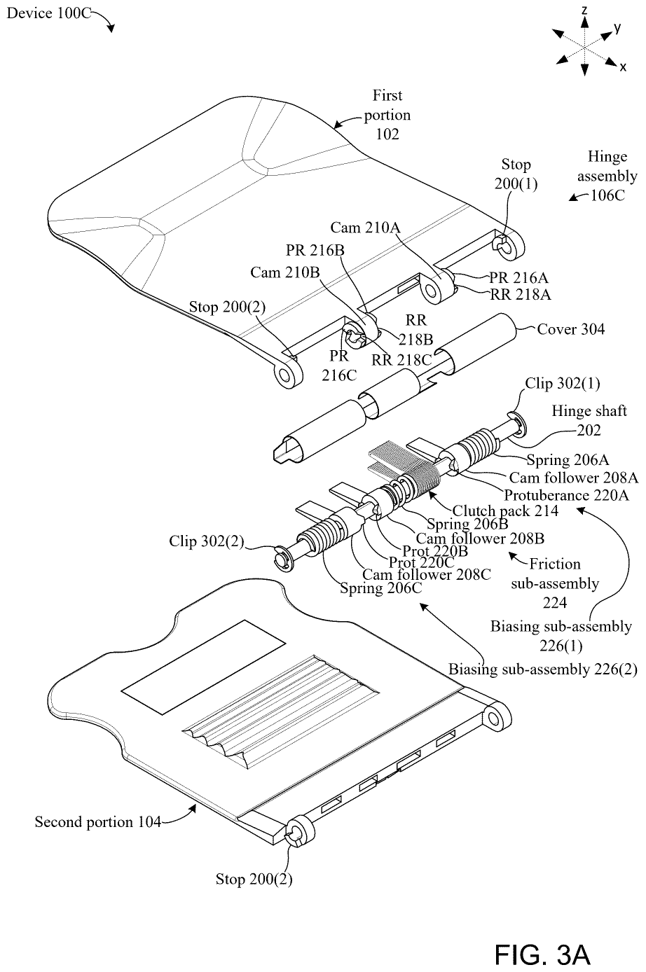

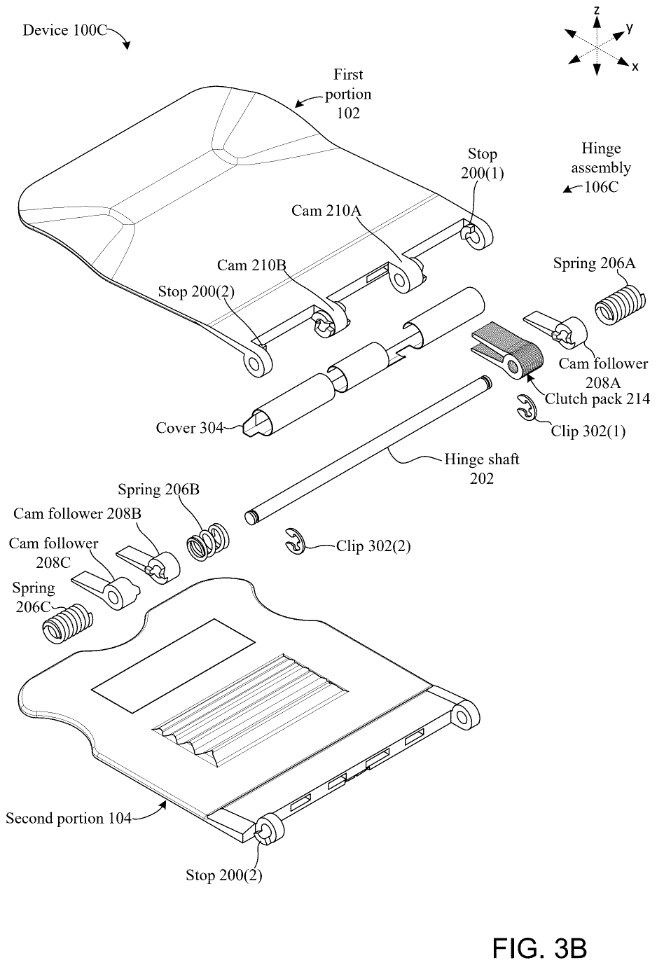

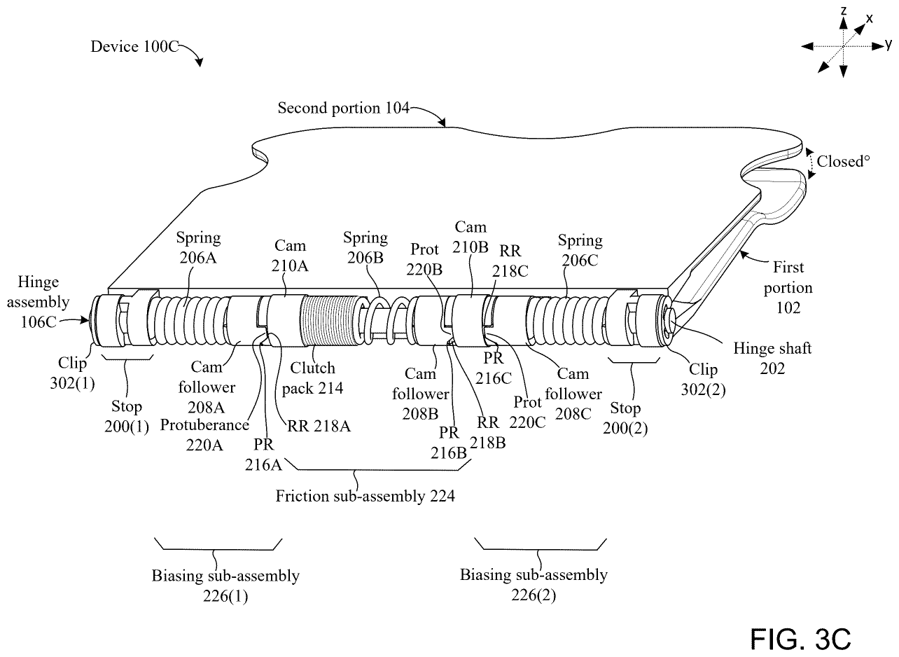

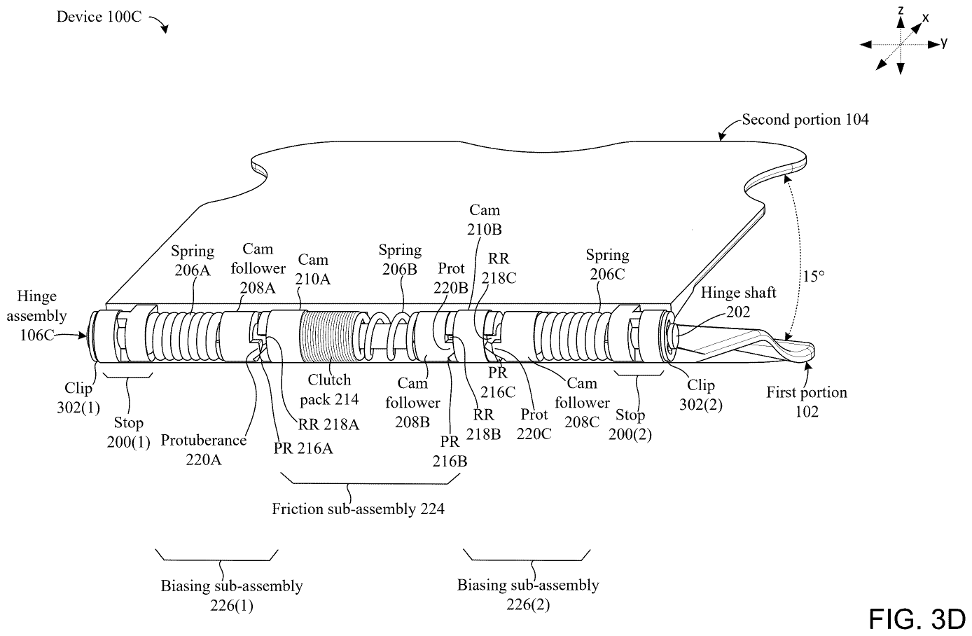

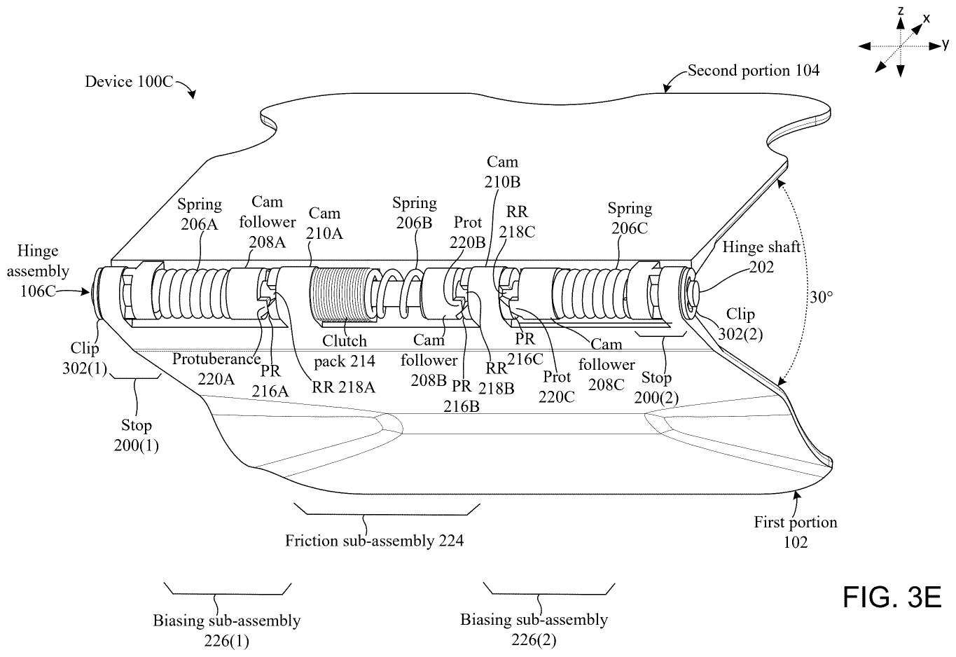

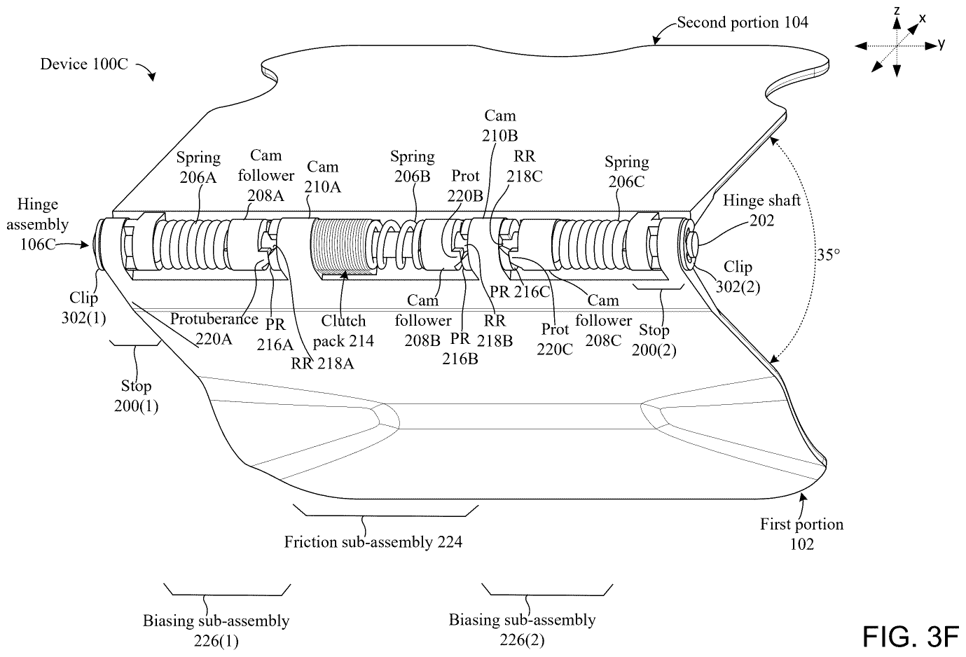

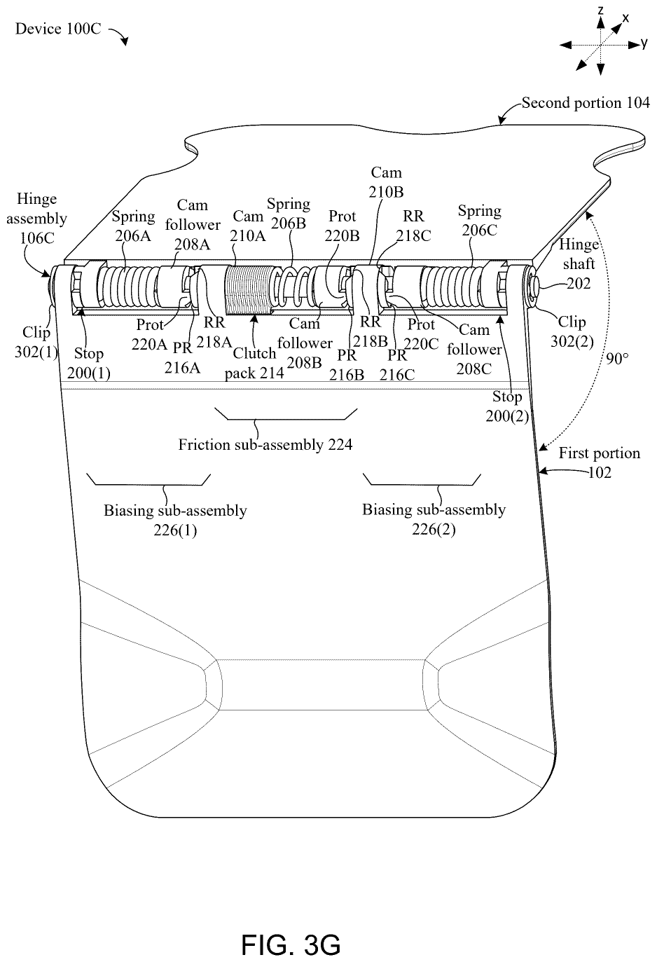

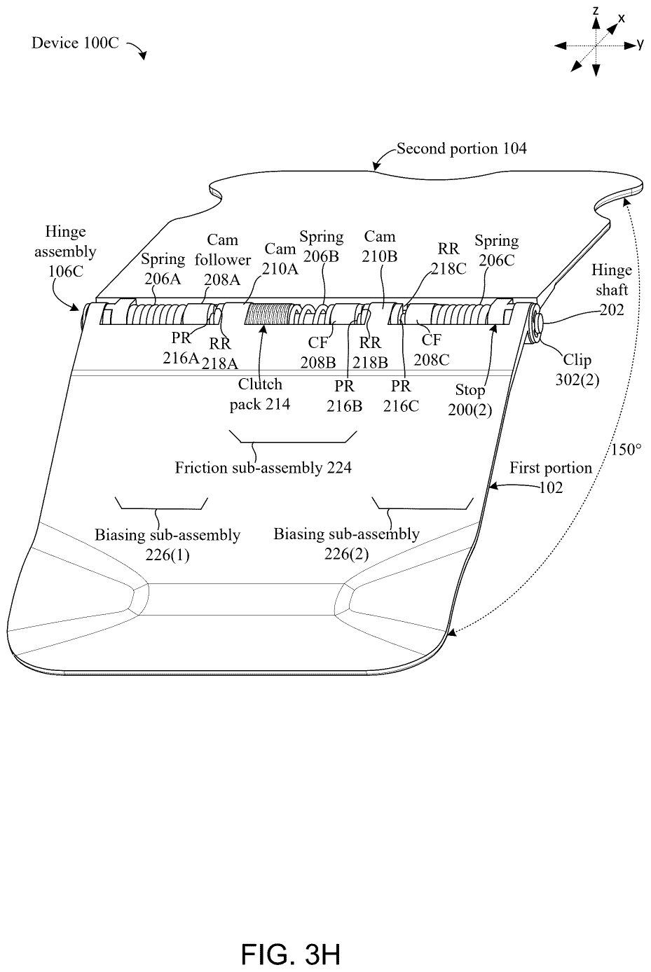

FIGS. 3A-3H collectively show another example device 100C. FIGS. 3A and 3B show partially exploded views of device 100C. FIG. 3C shows the device in a closed orientation. FIG. 3D shows the device in a 15-degree orientation. FIG. 3E shows the device in a 30-degree orientation. FIG. 3F shows the device in a 35-degree orientation. FIG. 3G shows the device in a 90-degree orientation. FIG. 3H shows the device in a fully-open 150-degree orientation. In this implementation, the closed and 30-degree orientations represent the biased sub-range and the 35, 90, and 150-degree orientations represent the friction sub-range. Note that no view shows all aspects of the device and the views should be considered collectively. Further, to provide multiple different views, FIGS. 3A and 3B show the device with the first portion 102 above the second portion 104, whereas FIGS. 3C-3H show the device with the second portion 104 above the first portion 102.

In this case, the hinge assembly 106C includes three compression springs 206A, 206B, and 206C, two axial cams 210A and 210B, and three cam followers 208A, 208B, and 208C, all of which are positioned on hinge shaft 202. The hinge assembly 106C also includes stops 200, clips 302, and a cover 304. In this implementation, the stops 200 define the range of rotation from a closed orientation of about −3.5 degrees to fully open orientation of about 150 degrees. The cam followers 208 and one side of the clutch pack 214 are received in slots in the second portion 104. The other side of the clutch pack 214 is received in a slot in the first portion 102. These slots are shown but not designated in FIGS. 3A and 3B. The slots for the cam followers can be slightly oversized in the y reference direction to allow movement of the cam followers 208 along the y reference axis (e.g., along the hinge axis). The clips 302 retain the other elements on the hinge shaft 202.

The friction sub-assembly 224 entails the backside (e.g., right side on the drawing page on FIGS. 3C-3H) of cam 210A, clutch pack 214, compression spring 206B, cam follower 208B, and the left side of cam 210B. Cam 210A and cam 210B are secured to the first portion in a manner that prevents them from moving along the y reference axis. The cam follower 208B is secured to the second portion 104 and can move along the y reference axis. The clutch pack 214, compression spring 206B, and cam follower 208B are captive between cam 210A and cam 210B. Note that the backside of cam 210A is a flat surface rather than a cammed surface. The friction sub-assembly 224 is sandwiched (e.g., interposed) between two biasing sub-assemblies 226(1) and 226(2). This configuration provides a technical solution that provides symmetrical forces along the hinge shaft 202 and thus reduces asymmetric torques that could contribute to component failure.

The biasing sub-assembly 226(1) includes spring 206A, cam follower 208A, and cam 210A in the −y reference direction from the friction sub-assembly 224 (e.g., left on the drawing page of FIGS. 3C-3H). In the +y reference direction from the friction sub-assembly 224 (e.g., right on the drawing page of FIGS. 3C-3H), the biasing sub-assembly 226(2) includes spring 206C, cam follower 208C, and cam 210B. The cam followers 208A-208C are slidably secured to the second portion 104.

In this implementation, as shown in FIG. 3C the biasing sub-assemblies'compression springs 206A and 206C are preloaded (e.g., compressed at the closed orientation). Thus, at the closed orientation of FIG. 3C, compression spring 206A is imparting a force on cam follower 208A towards cam 210A and similarly compression spring 206C is imparting a force onto cam follower 208C towards cam 210B.

Specifically, compression spring 206A is forcing the cam follower's protuberance 220A into the cam's recess region 218A. Even with the protuberance 220A ‘bottomed out’ in the recess region 218A, the preloaded compression spring 206A is still slightly compressed and continues to exert force on the cam follower 208A toward the cam 210A. Similarly, compression spring 206C is forcing the cam follower's protuberance 220C into the cam's recess region 218C Even with the protuberance 220C ‘bottomed out’ in the recess region 218C the preloaded compression spring 206C is still slightly compressed and continues to exert force on the cam follower 208C toward the cam 210B. As will be described in more below, rotating the first and second portions 102 and 104 will entail imparting force on the first and second portions to further compress compression springs 206A and 206C. Thus, the present concepts provide a technical solution where the device is biased to maintain the closed orientation unless sufficient force is imparted on the device to overcome the bias.

The biasing sub-assemblies 226 provide a closed orientation to a 30-degree orientation axial cam functionality. Specifically, cam follower 208A and axial cam 210A operate to provide a closed orientation to a 30-degree orientation axial cam functionality. Similarly, cam follower 208C and cam 210B operate to provide a closed to a 30-degree axial cam functionality. In this example, the biasing sub-assemblies 226 bias (e.g., closing biasing torque) the first and second portions to (e.g., toward) the closed orientation. Alternatively, the biasing sub-assemblies 226 could bias (e.g., opening biasing torque) the first and second portions to (e.g., away from) the closed orientation In this case, the bias to the closed orientation is achieved because the end of protuberance 220A is approximately as wide (angular span relative to the hinge axis) as the bottom of the recess region 218A. Similarly, the end of protuberance 220C is approximately as wide (angular span relative to the hinge axis) as the bottom of the recess region 218C. Thus, in the closed orientation, the end of protuberances 220A and 220C are bottomed out in recess regions 218A and 218C, respectively with little or no free rotation.

As shown in FIG. 3D, for rotation to occur from the closed orientation, the protuberances 220A and 220C have to climb the slanted cam surfaces 212A and 212C, respectively. Climbing the slanted cam surfaces 212A and 212C compresses springs 206A and 206C. Thus, sufficient rotational force has to be imparted on the first and second portions from an external source to overcome the biases imparted by the compression springs 206A and 206C. The protuberances 220A and 220C will reach the top of the slanted cam surfaces 212A and 212C and transition to the proud regions 216A and 216C at about the 30-degree orientation as shown in FIG. 3E. Transitioning to the proud regions 216A and 216C ends the bias sub-rotation.

In contrast, the friction sub-assembly's compression spring 206B is not preloaded (e.g., is fully extended in the closed orientation of FIG. 3C). Alternatively, spring 206B is preloaded with a small amount of force to prevent rattle within the clutch pack 214. Cam 210B and cam follower 208B operate to provide a 15-degree to 35-degree axial cam functionality. The recess region 218B has a greater angular span, by about 15 degrees in this example, than the end of protuberance 220B. Thus, as shown in FIGS. 3C and 3D, there is 15 degrees of free rotation from the closed orientation before the end of protuberance 220B contacts the slanted cam surfaces 212B. At that orientation, the end of protuberance 220B contacts the slanted cam surfaces 212B. As shown in FIG. 3E, further rotation causes the end of protuberance 220B to climb the slanted cam surfaces 212B, which moves the cam follower 208B in the −y reference direction. As the protuberance 220B rides up the cam surface 212B, the cam follower 208B is forced to move linearly and begins to compress the spring 206B and affects the clutch pack 214. The effect on the clutch pack 214 peaks at the proud region (e.g., top (flat)) 216B of the cam surface 212B as shown in FIG. 3F.

As shown in FIG. 3F, which is about 35 degrees of rotation, the interaction of the end of protuberance 220B and the slanted cam surfaces 212B compresses the spring 206B and is imparting a linear force on the clutch pack 214. The linear force on the clutch pack 214 creates a resistance to rotation of the first and second portions and starts the friction sub-rotation. The friction sub-rotation is maintained while the protuberance 220B remains on the proud region 216B from this point to the fully open orientation. Note, cams 210A and/or 210B and their associated protuberances 220 can be adjusted in slop angle, shape, and/or position, to tune the desired range of torques or friction throughout the system.

FIG. 3G shows an intermediate orientation of the friction sub-rotation of about 90 degrees. During the friction sub-rotation, which in this implementation is from the 35-degree orientation to the fully open 150-degree orientation, the friction sub-assembly 224 provides friction between the adjacent friction plates of the clutch pack 214. In contrast, the biasing sub-assemblies 226 are not creating a bias because the protuberances 220A and 220C continue to contact the proud regions 216A and 216C of cams 210A and 210B, respectively. The proud regions 216A and 216C are flat and thus the interaction with the protuberances does not create a bias to any orientations in the friction sub-rotation.

FIG. 3H shows the first and second portions 102 and 104 in the fully open orientation of about 150 degrees. Contact between protuberance 220B and proud region 216B continues to push the cam follower 208B in the −y reference direction (e.g., away from cam 210B). In turn, the cam follower 208B compresses the compression spring 206B against the clutch pack 214. The clutch pack's friction plates are forced together by the compressed spring 206B. The spring 206B remains compressed in the friction sub-rotation because the protuberance 220B of the cam follower 208B remains on the proud region 216B of axial cam 210B. The friction from the clutch pack 214 provides a technical solution of resistance to rotation to hold the first and second portions 102 and 104 at an individual orientation unless acted upon by an external force.

At this point, and throughout the friction sub-range of rotation, the biasing sub-assemblies 226 are not creating a bias to an individual orientation because the protuberances 220A and 220C, which are not readily visible at this orientation, continue to contact the proud regions 216A and 216C of cams 210A and 210C, respectively. The proud regions 216A and 216C are flat and thus the interaction with the protuberances 220A and 220C does not create a bias to any orientations in the friction sub-rotation. Thus, the present concepts provide a technical solution where the hinge assembly offers two different hinge functionalities depending on the orientation. Further, the functionalities are range specific (e.g., limited to sub-ranges of rotation) and thus do not counter or inhibit each other.

Various dual function hinge assemblies are described above that have a friction function in a first sub-range of rotation and a biasing function in a second sub-range of rotation. FIGS. 1A-1D show an example dual function hinge assembly integral in a folding computing device. FIGS. 2A-3H show details of example mechanisms of some hinge assembly implementations.

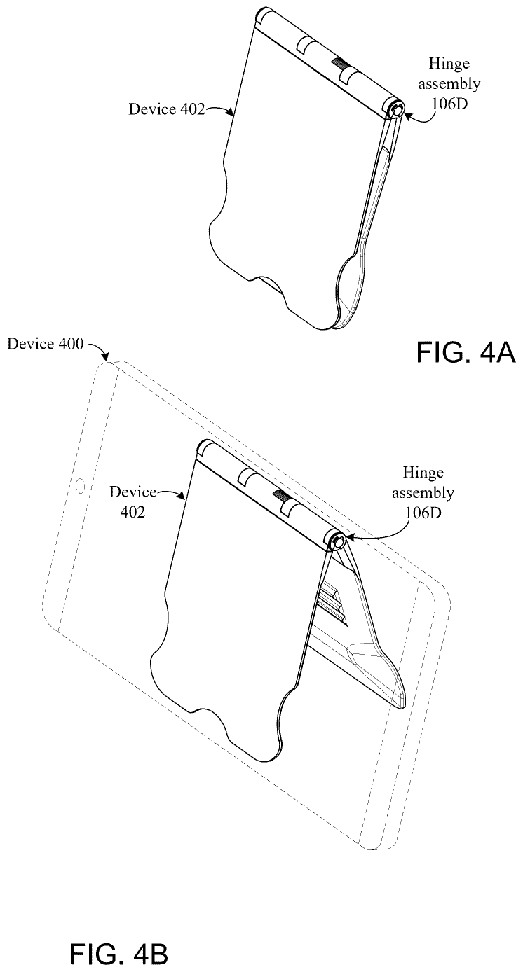

FIGS. 4A and 4B collectively show another dual function hinge assembly 106D that can be associated with a device 400. In this case, the hinge assembly 106D is integrated into an accessory device 402. FIG. 4A shows the accessory device 402 in isolation. The accessory device 402 is in the first (e.g., biased) sub-range of rotation and is providing the bias functionality.

FIG. 4B shows the accessory device 402 secured to device 400. The accessory device 402 is now in the second (e.g., friction) sub-range of rotation. The accessory device 402 is providing a friction functionality and is holding the device 400 in a desired posture. In various implementations, the accessory device 402 can be manifest as a case that snaps onto and protects the device 400. Alternatively, the accessory device 402 can be manifest as a clip that is removably secured to the device 400, such as by magnets. Other form factors are contemplated.

Individual elements of the hinge assemblies can be made from various materials, such as metals, plastics, and/or composites. These materials can be prepared in various ways, such as in the form of sheet metals, die cast metals, machined metals, 3D printed materials, molded or 3D printed plastics, and/or molded or 3D printed composites, among others, and/or any combination of these materials and/or preparations can be employed.

The present hinge assembly concepts can be utilized with any type of device, such as but not limited to notebook computers, smart phones, wearable smart devices, tablets, and/or other types of existing, developing, and/or yet to be developed devices.

Various methods of manufacture, assembly, and/or use for hinge assemblies and devices are contemplated beyond those shown above relative to FIGS. 1A-4B.

Although techniques, methods, devices, systems, etc., pertaining to hinge assemblies are described in language specific to structural features and/or methodological acts, it is to be understood that the subject matter defined in the appended claims is not limited to the specific features or acts described. Rather, the specific features and acts are disclosed as example forms of implementing the claimed methods, devices, systems, etc.

Various examples are described above. Additional examples are described below. One example includes a device comprising a first portion and a second portion that are rotatably secured by a hinge shaft through a range of rotation from a closed orientation to a fully open orientation, a friction sub-assembly positioned on the hinge shaft and configured to create resistance to rotation during a first sub-range of rotation from the fully opened orientation to an intermediary orientation, and a biasing sub-assembly positioned on the hinge shaft and configured to create a bias force towards the closed orientation during a second sub-range of rotation from the intermediary orientation to the closed orientation.

Another example can include any of the above and/or below examples where the friction sub-assembly comprises a clutch pack positioned on the hinge shaft and a first compression spring positioned on the hinge shaft, and wherein the biasing sub-assembly comprises a second compression spring positioned on the hinge shaft.

Another example can include any of the above and/or below examples where the device further comprises an axial cam positioned on the hinge shaft and configured to cause the first compression spring to be relatively more compressed in the first sub-range of rotation and relatively less compressed in the second sub-range of rotation.

Another example can include any of the above and/or below examples where the axial cam is positioned between the friction sub-assembly and the biasing sub-assembly.

Another example can include any of the above and/or below examples where the axial cam comprises a single axial cam that acts on both the friction sub-assembly and the biasing sub-assembly.

Another example can include any of the above and/or below examples where the axial cam comprises a first axial cam that is configured to act on the friction sub-assembly and a second axial cam that is configured to act on the biasing sub-assembly.

Another example can include any of the above and/or below examples where in the first sub-range of rotation the relatively more compressed first compression spring is configured to impart a force on the clutch pack and in the second sub-range of rotation the relatively less compressed first compression spring is configured not to impart a force on the clutch pack.

Another example can include any of the above and/or below examples where the device further comprises a second biasing sub-assembly positioned along the hinge shaft.

Another example can include any of the above and/or below examples where the friction sub-assembly is interposed along the hinge shaft between the biasing sub-assembly and the second biasing sub-assembly.

Another example can include any of the above and/or below examples where the device further comprises a first axial cam positioned on the hinge shaft between the biasing sub-assembly and the friction sub-assembly and a second axial cam positioned on the hinge shaft between the friction sub-assembly and the second biasing sub-assembly.

Another example includes a device comprising a first portion that includes a first display and a second portion that includes a second display, the first and second portions are rotatably secured by a hinge shaft through a range of rotation from a closed orientation to a fully open orientation, a friction sub-assembly positioned on the hinge shaft and configured to create resistance to rotation during a first sub-range of rotation that ranges from the fully opened orientation to an intermediary orientation, and a biasing sub-assembly positioned on the hinge shaft and configured to create a bias force during a second sub-range of rotation that ranges from the intermediary orientation to the closed orientation and the biasing force biases the first and second portions to an individual orientation within the second sub-range of rotation.

Another example can include any of the above and/or below examples where the biasing force is a closing biasing torque and the individual orientation is the closed orientation.

Another example can include any of the above and/or below examples where the biasing force is an opening biasing torque and the individual orientation is the intermediary orientation.

Another example can include any of the above and/or below examples where the intermediary orientation lies within a range of 10 degrees to 90 degrees.

Another example can include any of the above and/or below examples where the intermediary orientation is 30 degrees.

Another example can include any of the above and/or below examples where the biasing sub-assembly comprises a clutch pack.

Another example can include any of the above and/or below examples where the biasing sub-assembly comprises multiple detents associated with orientations within the first sub-range of rotation.

Another example can include any of the above and/or below examples where the device comprises a computing device or wherein the device comprises an accessory for a computing device.

Another example includes a device comprising a first portion and a second portion that are rotatably secured by a hinge shaft through a range of rotation from a closed orientation to a fully open orientation, a friction sub-assembly positioned on the hinge shaft and configured to create resistance to rotation during a first sub-range of rotation between the fully opened orientation and an intermediary orientation and to not create resistance to rotation during a second sub-range of rotation between the intermediary orientation and the closed orientation, and a biasing sub-assembly positioned on the hinge shaft and configured to create a bias force that biases the first and second portions to an individual orientation within the second sub-range of rotation and to not create a bias force that biases the first and second portions during the first sub-range of rotation.

Another example can include any of the above and/or below examples where the device further comprises an axial cam positioned on the hinge shaft and configured to rotate with rotation of the first and second portions and wherein the axial cam is configured to activate the friction sub-assembly and not the biasing sub-assembly in the first sub-range of rotation and to activate the biasing sub-assembly and not the friction sub-assembly in the second sub-range of rotation.

1. A device, comprising:
a first portion and a second portion that are rotatably secured by a hinge shaft through a range of rotation from a closed orientation to a fully open orientation;
a friction sub-assembly positioned on the hinge shaft and configured to create resistance to rotation during a first sub-range of rotation from the fully opened orientation to an intermediary orientation; and,
a biasing sub-assembly positioned on the hinge shaft and configured to create a bias force towards the closed orientation during a second sub-range of rotation from the intermediary orientation to the closed orientation.

2. The device of claim 1, wherein the friction sub-assembly comprises a clutch pack positioned on the hinge shaft and a first compression spring positioned on the hinge shaft, and wherein the biasing sub-assembly comprises a second compression spring positioned on the hinge shaft.

3. The device of claim 2, further comprising an axial cam positioned on the hinge shaft and configured to cause the first compression spring to be relatively more compressed in the first sub-range of rotation and relatively less compressed in the second sub-range of rotation.

4. The device of claim 3, wherein the axial cam is positioned between the friction sub-assembly and the biasing sub-assembly.

5. The device of claim 3, wherein the axial cam comprises a single axial cam that acts on both the friction sub-assembly and the biasing sub-assembly.

6. The device of claim 3, wherein the axial cam comprises a first axial cam that is configured to act on the friction sub-assembly and a second axial cam that is configured to act on the biasing sub-assembly.

7. The device of claim 3, wherein in the first sub-range of rotation the relatively more compressed first compression spring is configured to impart a force on the clutch pack and in the second sub-range of rotation the relatively less compressed first compression spring is configured not to impart a force on the clutch pack.

8. The device of claim 1, further comprising a second biasing sub-assembly positioned along the hinge shaft.

9. The device of claim 8, wherein the friction sub-assembly is interposed along the hinge shaft between the biasing sub-assembly and the second biasing sub-assembly.

10. The device of claim 9, further comprising a first axial cam positioned on the hinge shaft between the biasing sub-assembly and the friction sub-assembly and a second axial cam positioned on the hinge shaft between the friction sub-assembly and the second biasing sub-assembly.

11. A device, comprising:
a first portion that includes a first display and a second portion that includes a second display, the first and second portions are rotatably secured by a hinge shaft through a range of rotation from a closed orientation to a fully open orientation;
a friction sub-assembly positioned on the hinge shaft and configured to create resistance to rotation during a first sub-range of rotation that ranges from the fully opened orientation to an intermediary orientation; and,
a biasing sub-assembly positioned on the hinge shaft and configured to create a bias force during a second sub-range of rotation that ranges from the intermediary orientation to the closed orientation and the biasing force biases the first and second portions to an individual orientation within the second sub-range of rotation.

12. The device of claim 11, wherein the biasing force is a closing biasing torque and the individual orientation is the closed orientation.

13. The device of claim 11, wherein the biasing force is an opening biasing torque and the individual orientation is the intermediary orientation.

14. The device of claim 11, wherein the intermediary orientation lies within a range of 10 degrees to 90 degrees.

15. The device of claim 14, wherein the intermediary orientation is 30 degrees.

16. The device of claim 11, wherein the biasing sub-assembly comprises a clutch pack.

17. The device of claim 16, wherein the biasing sub-assembly comprises multiple detents associated with orientations within the first sub-range of rotation.

18. The device of claim 11, wherein the device comprises a computing device or wherein the device comprises an accessory for a computing device.

19. A device, comprising:
a first portion and a second portion that are rotatably secured by a hinge shaft through a range of rotation from a closed orientation to a fully open orientation;
a friction sub-assembly positioned on the hinge shaft and configured to create resistance to rotation during a first sub-range of rotation between the fully opened orientation and an intermediary orientation and to not create resistance to rotation during a second sub-range of rotation between the intermediary orientation and the closed orientation; and,
a biasing sub-assembly positioned on the hinge shaft and configured to create a bias force that biases the first and second portions to an individual orientation within the second sub-range of rotation and to not create a bias force that biases the first and second portions during the first sub-range of rotation.

20. The device of claim 19, further comprising an axial cam positioned on the hinge shaft and configured to rotate with rotation of the first and second portions and wherein the axial cam is configured to activate the friction sub-assembly and not the biasing sub-assembly in the first sub-range of rotation and to activate the biasing sub-assembly and not the friction sub-assembly in the second sub-range of rotation.
